(19) United States
(12) Patent Application Publication
(10) Pub. No.: US 2026/0202486 A1
(43) Pub. Date: Jul. 16, 2026

(54) STATE-OF-HEALTH FOR RECHARGEABLE BATTERY

(71) Applicant: Medtronic, Inc., Minneapolis, MN (US)

(72) Inventors: Gang Ji, Medina, MN (US); Zhi Fang, Maple Grove, MN (US)

(21) Appl. No.: 19/136,080

(22) PCT Filed: Nov. 28, 2023
(86) PCT No.: PCT/IB2023/061965

§ 371 Date: Jun. 5, 2025

Related U.S. Application Data
(60) Provisional application No. 63/387,799, filed on Dec. 16, 2022.

(51) Int. Cl. G01R 31/392; G01R 31/367

(52) U.S. Cl. CPC G01R 31/392; G01R 31/367

(57) ABSTRACT

Example devices and techniques are described herein for determining a relative state-of-charge of a battery. An example device includes memory, a battery, and processing circuitry coupled to the memory. The processing circuitry may determine a plurality of changes in a battery parameter over respective periods of time. The processing circuitry may determine an acceleration of the changes in the battery parameter based on the plurality of changes in the battery parameter over respective periods of time. Based at least in part on the acceleration of the changes in the battery parameter over time, the processing circuitry may generate a change battery indication relating to changing the battery and output the change battery indication.

This application claims the benefit of U.S. Provisional Patent Application Ser. No. 63/387,799, filed 16 Dec. 2022, the entire content of which is incorporated herein by reference.

### TECHNICAL FIELD

The disclosure relates to rechargeable batteries and, more particularly, to devices and techniques for determining a state-of-health of a rechargeable battery.

### BACKGROUND

Many devices, including medical devices, laptop computers, tablets, and cellular phones, among others, utilize rechargeable batteries. These devices also may include processing circuitry, that may monitor battery parameters and provide a user of the device with a representation of the state-of-charge of the battery, such as how fully charged the battery may be.

### SUMMARY

In some aspects, this disclosure is directed to devices that utilize rechargeable batteries, such as medical devices (including implantable medical devices (IMDs) and/or external medical devices), laptop computers, tablets, or cellular phones, for example, and techniques for such devices to determine an acceleration of changes in battery parameters, such as an incremental capacity fade or incremental impedance growth of the battery.

As a rechargeable battery ages in the field (e.g., the rechargeable battery is actually being used to power a device or portions of a device), the battery capacity of the rechargeable battery fades and the internal impedance of the battery grows. Depending on the actual use conditions of each battery, the capacity fade rate and/or the internal impedance growth rate may differ significantly among the deployed batteries. The rechargeable battery may eventually reach an end-of-service (EOS) when the rechargeable battery is unable to, or is not recommended to (e.g., by a battery or device manufacturer), power the device to function as intended. For example, the rechargeable battery may fail to meet the energy requirement placed on the rechargeable battery by the device the rechargeable battery is powering. EOS may be a percentage of an original battery capacity, such as 80%, and may be defined by the battery or device manufacturer.

As such, it may be desirable to determine that the rechargeable battery is approaching such an EOS state, prior to the rechargeable battery reaching the EOS state, and provide an indication, warning, notification, or the like, that the battery should be changed. This may provide a user with an opportunity to change, or have changed, the rechargeable battery (or the device including the rechargeable battery where the battery cannot be separately replaced) prior to the rechargeable battery reaching the EOS state, at a time convenient to the user, thereby avoiding a situation where the rechargeable battery reaches the EOS at an inopportune time.

For example, processing circuitry of a device may detect an acceleration of changes in a battery parameter, and based on the detection of the accelerating changes in the battery parameter, generate and/or output an indication to inform a user of the device that the user should change, or have changed, the rechargeable battery. In some examples, the changes in the battery parameter include an incremental capacity fade rate or an incremental impedance growth rate. A capacity fade rate may be the rate at which the capacity of the rechargeable battery fades over time (e.g., a slope of a capacity fade curve). An impendence growth rate may be the rate at which the internal impedance of the rechargeable battery grows over time (e.g., a slope of an impedance growth rate curve). An incremental capacity fade rate may be the rate at which the capacity of the rechargeable battery fades over a given increment of time (e.g., a portion of the total time at which the capacity of the rechargeable battery is fading). An incremental impendence growth rate may be the rate at which the internal impedance of the rechargeable battery grows over a given increment of time (e.g., a portion of the total time at which the impedance of the rechargeable battery is growing).

In some examples, the processing circuitry may detect the accelerating changing in the battery parameter when either, or both, of the following conditions are true: 1) the second derivative of changes in the battery parameter over time meets a second derivative threshold (e.g., is less than (or less than or equal to) a predefined threshold); or 2) the most recent (e.g., present) measured change in the battery parameter (e.g., change between the present determined value and the immediate prior determined value) meets a difference threshold (is greater than, or greater than or equal to). By detecting the accelerating change in the battery parameter and generating and/or outputting the change battery indication, the processing circuitry may notify a user that the rechargeable battery should be replaced, which may reduce or avoid the possibility of a situation where the rechargeable battery reaches EOS and is unable to power the device fully. The techniques of this disclosure may include an improvement over conventional techniques for determining when to notify a user when to replace a battery, and thus may improve the functioning of a device, such as an implantable medical device (IMD). This may be important, for example, for a rechargeable battery powering an IMD, which may be delivering therapy to a patient. In such an example, the IMD may not be capable of delivering such therapy to the patient when the rechargeable battery reaches EOS. This may impact a quality of life, health, or the like for such a patient.

In some examples, the processing circuitry may also predict a time to end-of-service (EOS) for the rechargeable battery. The processing circuitry may compare the time-to-EOS to a time-to-EOS threshold. The time-to-EOS threshold may be an amount of time, such as a predetermined number of months, weeks, days, or the like. When the time-to-EOS meets the time-to-EOS threshold (e.g., is less than, or less than or equal to the predetermined amount of time), the processing circuitry may generate and/or output another indication (e.g., an EOS warning). This indication may include a message, for example, directed to the user of the device powered by the rechargeable battery, to replace the battery, that the battery is nearing EOS, and/or including an estimate of the amount of time left until EOS. When the EOS is reached (e.g., the rechargeable battery cannot power the device to perform the intended function of the device), the processing circuitry may generate yet another indication (e.g., an EOS notification) directed to the user of the device powered by the rechargeable battery to alert user that the battery has reached the EOS and/or may no longer meet the requirement placed on the battery by the device the battery is powering.

By generating and/or outputting the EOS warning and/or the EOS notification, the processing circuitry may inform the patient that the rechargeable battery is nearing EOS or that the rechargeable battery has reached EOS and the rechargeable battery is no longer able to power the device to function as intended. For example, in the case of an IMD which is configured to deliver therapy to the patient, the IMD may no longer be able to deliver efficacious therapy to the patient. This second indication may prompt a patient to replace the rechargeable battery if earlier indication(s) did not result in the patient replacing, or having replaced, the rechargeable battery.

In one example, the disclosure is directed to a device including a memory; a battery; processing circuitry coupled to the memory, the processing circuitry being configured to: determine a plurality of changes in a battery parameter of a battery over respective periods of time; determine an acceleration of the changes in the battery parameter based on the plurality of changes in the battery parameter over the respective periods of time; based at least in part on the acceleration of the changes in the battery parameter over time, generate a change battery indication relating to changing the battery; and output the change battery indication.

In another example, the disclosure is directed to a method including determining a plurality of changes in a battery parameter of a battery over respective periods of time; determining an acceleration of the changes in the battery parameter based on the plurality of changes in the battery parameter over the respective periods of time; based at least in part on the acceleration of the changes in the battery parameter over time, generating a change battery indication relating to changing the battery; and outputting the change battery indication.

In another example, the disclosure is directed to a non-transitory storage medium comprising instructions that when executed by one or more processors cause the one or more processors to: determine a plurality of changes in a battery parameter of a battery over respective periods of time; determine an acceleration of the changes in the battery parameter based on the plurality of changes in the battery parameter over the respective periods of time; based at least in part on the acceleration of the changes in the battery parameter over time, generate a change battery indication relating to changing the battery; and output the change battery indication.

The details of one or more examples of the disclosure are set forth in the accompanying drawings and the description below. Other features, objects, and advantages of the disclosure will be apparent from the description and drawings, and from the claims.

### BRIEF DESCRIPTION OF DRAWINGS

FIG. 1 is a block diagram of an example system for monitoring a state-of-health of a rechargeable battery according to one or more aspects of this disclosure.

FIG. 2 is a graphical diagram illustrating battery capacity over time, a first derivative of a change in battery capacity over time, and a second derivative of the change in battery capacity over time according to one or more aspects of this disclosure.

FIG. 3 is graphical diagram illustrating example techniques for determining accelerating battery parameter changes over time with relatively frequent battery parameter monitoring according to one or more aspects of this disclosure.

FIG. 4 is a graphical diagram illustrating example techniques for determining accelerating battery parameter changes over time with relatively infrequent battery parameter monitoring according to one or more aspects of this disclosure.

FIG. 5 is a conceptual diagram illustrating determined data points of battery parameter changes over time with relatively infrequent battery parameter monitoring according to one or more aspects of this disclosure.

FIG. 6 is a graphical diagram illustrating an example battery capacity fade curve over time.

FIG. 7 is a graphical diagram illustrating example EOS prediction techniques according to one or more aspects of this disclosure.

FIG. 8 is a flow diagram illustrating example state-of-health techniques according to one or more aspects of this disclosure.

### DETAILED DESCRIPTION

A variety of devices may utilize rechargeable batteries as a power source for operational power. For example, medical devices, such as an insulin pump, an IMD that provides cardiac rhythm management therapy to a patient, an IMD that monitors one or more physiological parameters of the patient, an IMD that provides neurostimulation therapy to the patient, imaging devices, robotic devices, navigation devices, or the like, may include a rechargeable battery to supply power for the generation of electrical therapy or other functions of the device. As another example, a left-ventricular assist device (LVAD) may include a rechargeable battery to supply power for a pump and other functions of the LVAD. Other devices, such as laptop computers, tablet computers, cellular phones, wireless speakers, power tools, and other devices may also utilize rechargeable batteries as a power source for operational power.

The ability of a rechargeable battery to power intended functions of a device which the rechargeable battery powers may be critical for the safe and effective operation of devices, such as many medical devices and applications thereof. For example, a user may want to replace a rechargeable battery before the rechargeable battery reaches the EOS of the rechargeable battery (e.g., as defined by the battery manufacturer, such as 80% of the original battery capacity) so as to not have the medical device fail to function as intended at an inconvenient time. In the case of some medical devices, such as IMDs, replacing the rechargeable battery may include replacing the entire device. In the case of a smartphone or other cellular phone, a user may want to replace the rechargeable battery before the rechargeable battery reaches the EOS of the rechargeable battery so as to not be somewhere without an ability to make or receive phone calls, send or receive text messages, access the Internet, receive navigation instructions, or the like.

As mentioned above, as a rechargeable battery ages in the field, the battery capacity of the rechargeable battery fades and the internal impedance of the battery grows. Depending on the actual use conditions of each battery, the capacity fade rate and/or the internal impedance growth rate may differ significantly among the deployed batteries. For example, a rechargeable battery powering a device having a relatively large current draw (e.g., an electrical stimulation therapy device) may have a shorter time-to-EOS than a rechargeable battery powering a device having a relatively small current draw (e.g., an insertable cardiac monitor). As such, estimating a time-to-EOS of a rechargeable battery is more complicated than just subtracting an amount of time the rechargeable battery has been in the field from a time period supposedly associated with the serviceable lifespan of the rechargeable battery. For example, if a rechargeable battery is supposed be reach EOS after 10 years and the rechargeable battery has been used for 7 years, one cannot merely subtract 7 years from 10 years and estimate the time-to-EOS as 3 years with any degree of accuracy as different batteries (even different batteries of the same composition and construction) are subject to different use conditions.

Acceleration of changes in battery parameters, such as incremental capacity fade rate and/or incremental impedance growth rate, may be an indicator of degrading health of the rechargeable battery. Some rechargeable batteries, such as batteries containing lithium (e.g., lithium-ion batteries) may pose a safety concern as they age, as the battery may heat up, for example, due to potential lithium plating. Therefore, it may also be desirable to monitor a state-of-health of a rechargeable battery and provide an indication to a user of the device powered by the rechargeable battery to change or have changed the rechargeable battery, for example, when there is an acceleration of changes in a battery parameter and/or when the battery reaches an EOS state to avoid or lessen safety concerns.

In the example in which the device that the rechargeable battery powers is an IMD, a patient may be completely unaware that a rechargeable battery has reached an EOS state. For example, some therapy is delivered only when certain parameters are met. For example, an implantable defibrillator may only deliver a shock to a heart of the patient when the implantable defibrillator determines that certain condition(s) are met such that a shock is medically desirable. Other devices, such as electrical stimulation devices or pacemakers, may deliver therapy that is sub-threshold, such that the actual delivery of the therapy is not perceived by the patient. With such an IMD, the patient may be unlikely to become aware that the rechargeable battery of the IMD has reached the EOS state solely based on the device being under powered and ceasing to perform all expected functions.

As such, it may be desirable to provide one or more indications that a rechargeable battery is nearing the EOS state, and if not replaced prior to the EOS state, provide a further indication that the rechargeable battery has reached the EOS state. Processing circuitry of a device powered by a rechargeable battery may provide indications based on the determination that changes in a battery parameter are accelerating, based on the predicted time-to-EOS of the battery being within a time-to-EOS threshold of the EOS, and/or based on the reaching of the EOS state.

This disclosure discusses determining a battery parameter, such as capacity or impedance, at various times, such as to determine a plurality of changes in the battery parameter. This disclosure contemplates determining such battery parameters through any techniques, including conventional techniques which are known to those skilled in the art.

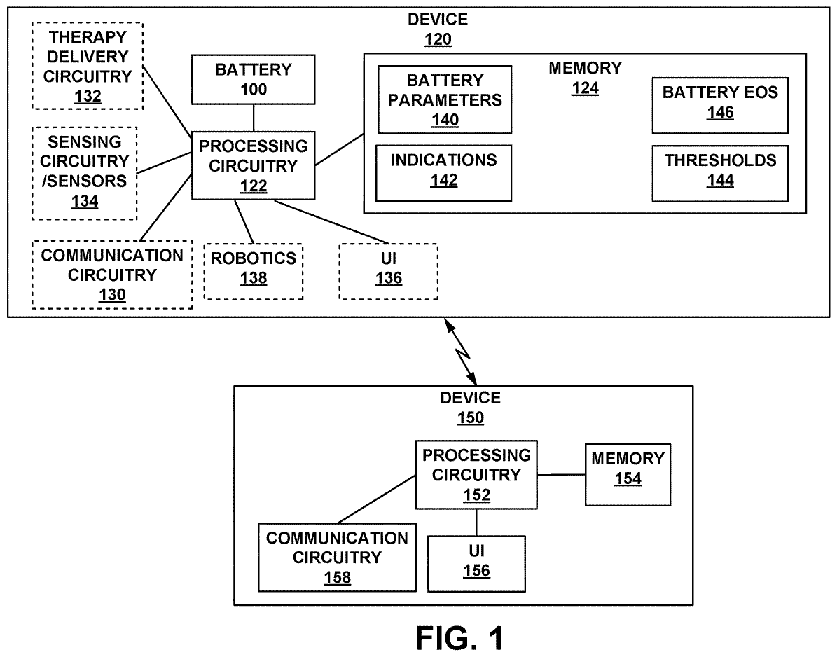

FIG. 1 is a block diagram of an example system for monitoring a state-of-health of a rechargeable battery according to one or more aspects of this disclosure. FIG. 1 depicts a device 120 and device 150. Device 120 may be a medical device, a laptop computer, a tablet computer, a cellular phone, or any other device that utilizes a rechargeable battery to power one or more portions of the device. Device 150 may be a computing device, such as a laptop computer, a tablet computer, a cellular phone, a desktop computer, a workstation, or other device that may be configured to communicate with device 120 and output an indication regarding a state-of-health of rechargeable battery 100.

Device 120 includes rechargeable battery 100, processing circuitry 122, and memory 124. In some examples, device 120 may include other circuitry or functionality. For example, device 120 may include therapy delivery circuitry 132, in examples where device 120 is configured to deliver therapy to a user of device 120. For example, therapy delivery circuitry 132 may include circuitry for generating an electrical stimulation signal, a shock, or other therapy, and delivering the therapy via electrodes (not shown), such as charge pumps, current/voltage sources, and switches. In some examples, therapy delivery circuitry 132 may include circuitry for controlling a reservoir which may hold a medication, such as insulin, and therapy delivery circuitry 132 may be configured to control the reservoir (not shown) to release a bolus of medication based on one or more sensed physiological parameters, such as a blood sugar level.

In some examples, device 120 may include sensing circuitry/sensors 134. Sensing circuitry/sensors 134 may be configured to sense one or more physiological parameters of a user (e.g., a patient), sense a location of the user of device 120, sense an orientation of device 120, or the like. In some examples, processing circuitry 122 may control therapy delivery circuitry 132 or other elements of device 120 based on output of sensing circuitry/sensors 134. In some examples, sensing circuitry/sensors 134 may include one or more imaging sensors configured to sense anatomy of a patient.

In some examples, device 120 may include communication circuitry 130. Communication circuitry 130 may be configured to communicate with other devices, such as device 150. Communication circuitry 130 may communicate via wired, wireless, optical, or other protocols.

In some examples, device 120 may include robotics 138, such as electrically controlled mechanical device(s) which processing circuitry 122 may control. In the example where device 120 represents a robotic imaging device, processing circuitry 122 may control movement of robotics 138 to align imaging sensor(s) of sensing circuitry/sensors 134 to sense anatomy of interest of the patient.

In some examples, device 120 may include a user interface (UI) 136. UI 136 may include one or more input devices and one or more output device(s). UI 136 may facilitate a user interacting with device 120. For example, any of the indications described herein may be provided to a user via UI 136. UI 136 may include a display, such as an LCD or LED display or other type of screen, one or more LEDs, one or more speakers, a haptic device, or other devices configured to present information. For example, UI 136 may be configured to inform a user to replace, or have replaced, battery 100, that battery 100 is nearing EOS, of a prediction of how much time exists before battery 100 reaches EOS, that battery 100 has reached EOS, or the like. As such, a user of device 120 may take action to replace battery 100 and avoid or minimize an amount of time with which battery 100 is not able to adequately power device 120. For example, such an indication may be visual, auditory, haptic, and/or the like. In some examples, the indication may include a prediction of the time-to-EOS (e.g., 2.5 months to EOS), the EOS itself (e.g., EOS is on or about Jan. 6, 2023), or the like.

In addition, UI 136 may include input mechanism(s) to receive input from the user. The input mechanisms(s) may include, for example, buttons, a keypad (e.g., an alphanumeric keypad), a peripheral pointing device, one or more microphones, or another input mechanism.

Battery 100 may be a rechargeable battery that provides power to device 120 and/or the components of device 120. Processing circuitry 122 may include one or more general purpose microprocessors, digital signal processors (DSPs), application specific integrated circuits (ASICs), field programmable logic arrays (FPGAs), or other equivalent integrated or discrete logic circuitry. Processing circuitry 122 may be configured to execute computer-readable instructions, which may be stored in memory 124, to provide various functionality to device 120.

Memory 124 may store such instructions as mentioned above. Memory 124 may also store battery parameters 140, indications 142, thresholds 144, and/or battery EOS 146. Battery parameters 140 may include parameters of rechargeable battery 100 determined over time, and any data based on the determined parameters or used to determine such parameters, such as values of the parameter at various times, determined incremental changes in the battery parameters over time, or the like. For example, processing circuitry 122 may determine a battery capacity of rechargeable battery 100 at different times and store the determined battery capacities in battery parameters 140. Additionally, or alternatively, processing circuitry 122 may determine incremental changes in the battery capacity, such as incremental fades in between consecutive determined battery capacities. Additionally, or alternatively, processing circuitry 122 may determine incremental fade rates associated with the incremental fades and store the incremental fade rates in battery parameters 140. In some examples, battery parameters 140 may store parameters associated with battery impedance or battery impedance growth, rather than, or in addition to, storing parameters associated with battery capacity and battery capacity fade.

Memory 124 may also store indications 142. Indications 142 may include flags and/or generated indications relating to accelerating changes to a battery parameter. For example, indications 142 may store a flag indicative of whether the first condition is met, a flag indicative of whether the second condition is met, an indication for output that the user should replace, or have replaced, rechargeable battery 100, an indication for output that rechargeable battery 100 is nearing EOS, an indication for output that rechargeable battery 100 has reached EOS, or the like. The first condition may be that the second derivative of a plurality of changes in a battery parameter meets a second derivative threshold. The second condition may be that a present incremental change in the battery parameter meets a difference threshold. For example, the difference threshold may include an average of a plurality of past incremental changes in the battery parameter plus a percentage of the average of a plurality of past incremental changes in the battery parameter. For example, processing circuitry 122 may change a value of the flags based on a determination of whether the first condition or the second condition is met and may store the value of the flags in indications 142. Additionally, or alternatively, processing circuitry 122 may generate one or more indications for output, as described herein, and store the one or more indications in indications 142.

Memory 124 may also store thresholds 144. Thresholds 144 may include, for example a second derivative threshold, a difference threshold, and/or a time-to-EOS threshold. Processing circuitry 122 may use the second derivative threshold when determining whether a second derivative of the incremental changes in a parameter, such as incremental changes in capacity (e.g., incremental capacity fade), are indicative of a downturn in the state-of-health of rechargeable battery 100 which may warrant replacing rechargeable battery 100. Processing circuitry 122 may use the difference threshold when determining whether a present change in the battery parameter (e.g., an incremental change from the immediate previous determined battery parameter to the present determined battery parameter) is indicative of a downturn in the state-of-health of rechargeable battery 100 which may warrant replacing rechargeable battery 100. The difference threshold may be an average of previous incremental changes in the parameter plus a percentage of the average of previous incremental changes in the parameter (e.g., the average of previous incremental changes in the parameter plus 50% of the average of previous incremental changes in the parameter, which may equal 150% of the average of previous incremental changes in the parameter. The average of previous incremental changes in the parameter may be an average of a predetermined number of previous changes (e.g., a number in the range of 3-10) or an average of all previous changes. Processing circuitry 122 may use the time-to-EOS threshold when determining whether to generate and/or output an EOS warning indicating that rechargeable battery 100 is within a predetermined time until EOS. Thresholds 144 may be programmable by a user. For example, thresholds 144 may be programmed into device 120 via UI 136 and/or UI 156 of device 150 via communication circuitry 158 and communication circuitry 130. By having thresholds 144 be programmable, a manufacturer or user of a device, such as device 120, may tailor the generation and/or output of any indications to a particular device or particular use case of the device.

Memory 124 may also store battery EOS 146. Battery EOS 146 may include a determined or estimated battery EOS date. For example, processing circuitry 122 may determine an estimated battery EOS date for rechargeable battery 100 and store the determined estimated battery EOS date in battery EOS 146. For example, processing circuitry 122 may compare a present date to battery EOS 146 to determine whether or not to generate and/or output an indication that rechargeable battery 100 has reached EOS.

Device 150 may be a general-purpose computing device, such as a smartphone, a laptop computer, a tablet computer, a desktop computer, a workstation, or the like. In some examples, device 150 may be a specific purpose computing device, whose function is specifically designed to interact with device 120. Device 150 may include processing circuitry 152, memory 154, user interface 156, and communication circuitry 158. In some examples, device 150 may include fewer or more components than those shown in FIG. 1.

Processing circuitry 152 may include one or more general purpose microprocessors, digital signal processors (DSPs), application specific integrated circuits (ASICs), field programmable logic arrays (FPGAs), or other equivalent integrated or discrete logic circuitry. Processing circuitry 152 may be configured to execute computer-readable instructions, which may be stored in memory 154, to provide various functionality to device 150.

Communication circuitry 158 may be configured to communicate with communication circuitry 130 of device 120. Communication circuitry 158 may communicate via wired, wireless, optical, or other protocols. For example, under the control of processing circuitry 152, communication circuitry 158 may provide instructions to, or receive data, including any generated indications, from device 120. Processing circuitry 152 may utilize such generated indications to provide information to a user via UI 156.

UI 156 may include one or more input devices and one or more output device(s). UI 156 may facilitate a user interacting with device 150. In some examples, such as in the example where device 120 is an IMD, UI 156 of device 150 may be used by a user to interact with device 120 via communication circuitry 130 and communication circuitry 158. For example, any of the indications described herein may be provided to a user via UI 156. UI 156 may include a display, such as an LCD or LED display or other type of screen, one or more LEDs, one or more speakers, a haptic device, or other devices configured to present information. For example, UI 156 may be configured to inform a user to replace, or have replaced, battery 100, that battery 100 is nearing EOS, of a prediction of how much time exists before battery 100 reaches EOS, that battery 100 has reached EOS, or the like. As such, a user of device 120 may take action to replace battery 100 and avoid or minimize an amount of time with which battery 100 is not able to adequately power device 120. For example, such an indication may be visual, auditory, haptic, and/or the like. In some examples, the indication may include a prediction of the time-to-EOS (e.g., 2.5 months to EOS, EOS is on or about Jan. 6, 2023, or the like)

In addition, UI 156 may include input mechanism(s) to receive input from the user. The input mechanisms(s) may include, for example, buttons, a keypad (e.g., an alphanumeric keypad), a peripheral pointing device, one or more microphones, or another input mechanism.

Memory 154 may store instructions for computer-readable execution by processing circuitry 152. In some examples, memory 154 may store any, or all, of battery parameters 140, indications 142, thresholds 144, and/or battery EOS 146.

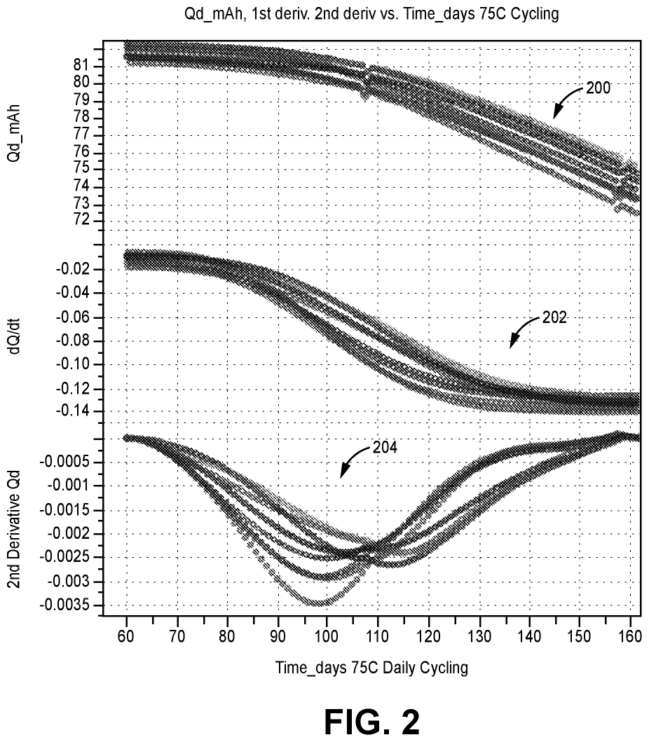

FIG. 2 is a graphical diagram illustrating battery capacity over time, a first derivative of a change in battery capacity over time, and a second derivative of the change in battery capacity over time according to one or more aspects of this disclosure. While the example of FIG. 2 relates to fading battery capacity, this discussion may also be applicable to other changing battery parameters, such as battery impedance growth.

Graph 200 depicts a plurality of curves, each of which represents the battery capacity (Y-axis) of a respective rechargeable battery over time (X-axis) during a portion of the life cycle of the respective rechargeable battery. As can be seen, the battery capacity of the rechargeable batteries generally decreases over time. This may be due to chemical reactions within the rechargeable batteries.

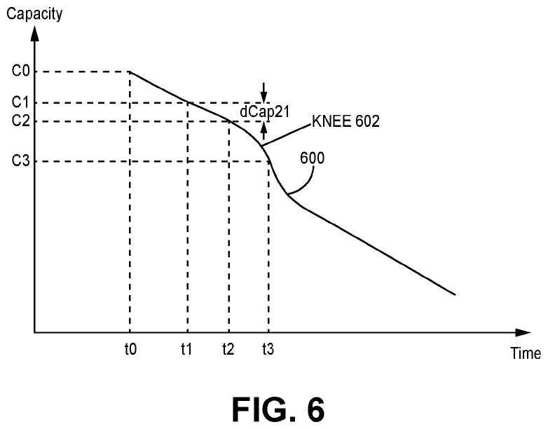

Graph 202 depicts a first derivative of the change in the battery capacity over time of the plurality of curves of graph 200. As can be seen, there is an acceleration of the change in battery capacity followed by a deceleration of the change in battery capacity. Such an acceleration followed by a deceleration may sometimes cause a knee-like appearance in a graph of the change in battery capacity over time (see, e.g., FIG. 6). As such, an attempt to detect such a knee-like appearance in a battery capacity graph may be referred to as knee detection. As can be seen in graph 202, knee detection is not visually as apparent as in the example of FIG. 6, which is discussed herein later.

Graph 204 depicts a second derivative of the change in the battery capacity over time of the plurality of curves of graph 200. As can be seen large dips or troughs appear in the curves of graph 204. These dips or troughs may correspond in time to a change from an acceleration to a deceleration in the plurality of curves of graph 202. For example, the lowest point in the dip or trough may correspond to a time that the changes in the battery capacity over time stop accelerating and begin decelerating. These dips or troughs (and/or any point therein) may be more easily detected than the acceleration and/or deceleration of the curves of graph 202. Therefore, it may be desirable to monitor a second derivative of a change in a battery parameter (e.g., incremental battery capacity fade and/or incremental impedance growth) over time. By monitoring a second derivative of a change in a battery parameter over time and determining whether a parameter meets a second derivative threshold (e.g., is less than the second derivative threshold or is less than or equal to the second derivative threshold), processing circuitry 122 may determine that the second derivative of the battery parameter has entered such a dip or trough, which may be indicative of the change in the battery parameter accelerating. The second derivative threshold may be a predetermined value, such as a value between 0 and −1. In some examples, the second derivative threshold may be in the range of −0.001 to −0.002. In other examples, the second derivative threshold may be in the range of −0.5 to −0.9, or other negative number below 1.

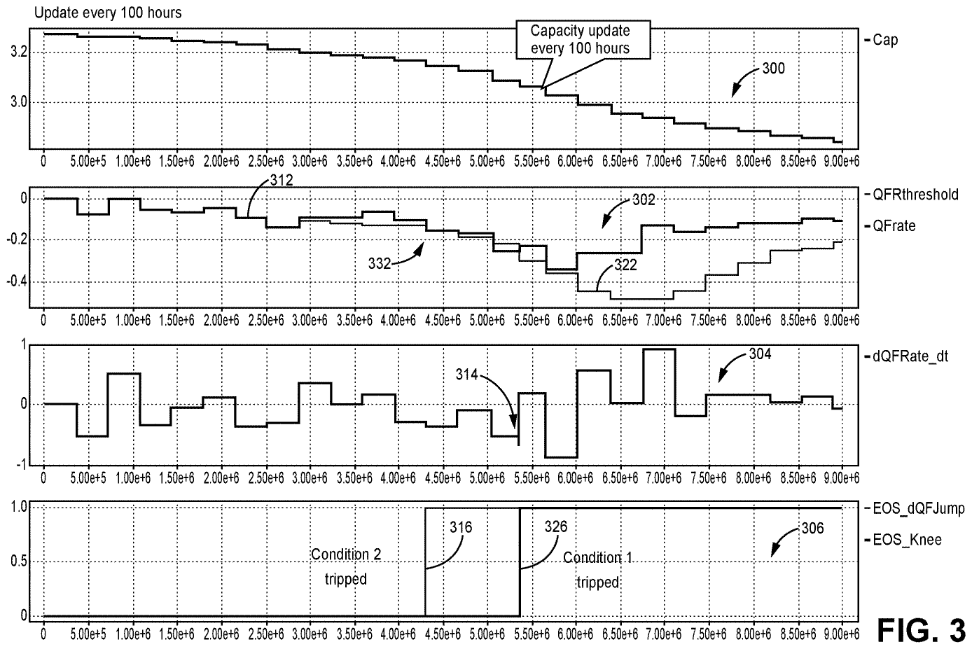

FIG. 3 is graphical diagram illustrating example techniques for determining accelerating battery parameter changes over time with relatively frequent battery parameter monitoring according to one or more aspects of this disclosure. While the example of FIG. 3 relates to fading battery capacity, the discussion may also be applicable to other changing battery parameters, such as battery impedance growth.

Graph 300 represents a determined battery capacity (Y-axis) over time (X-axis). For example, 5.00e+5 on the x-axis represents 5×10⁵ seconds or 500,000 seconds. In this example, processing circuitry 122 determines a battery capacity of rechargeable battery 100 every 100 hours. As can be seen, the battery capacity of rechargeable battery 100 declines over time. In the example of FIG. 3, the battery capacity fade rate accelerates from around 4×10⁶ seconds to 6.5×10⁶ seconds (around 1.6 to 2.6 months).

Graph 302 includes a representation of QFrate (e.g., incremental capacity fade rate) over time 312 and a representation of QFRthreshold (e.g., the difference threshold) 322. At time(s) 332, QFrate over time 312 and QFRthreshold over time 322 are equal. Thus, at time 332, the second condition may be met, e.g., the present incremental capacity fade rate may meet the difference threshold. For example, at time 332, the present (e.g., latest) incremental capacity fade rate may be equal to or higher than the average of past 4 incremental capacity fade rates by 80% (e.g., the difference threshold may be the average of past 4 incremental capacity fade rates plus 80% of the average of past 4 incremental capacity fade rates or 180% of the average of the past 4 incremental capacity fade rates), thus meeting the difference threshold. It should be noted that the difference threshold may vary from this example. For example, the difference threshold may include a percentage of the average of the past incremental capacity fade rates, or a percentage of the latest incremental capacity fade rate, such as 20%, 40%, 60%, 80% or any other percentage value. In some examples, the percentage value is positive.

In the example of graph 302, the second condition becomes true at around 4.3×10⁶ seconds and processing circuitry 122 may set a flag, e.g., EOS_dQFJump 316, from 0 to 1 as shown in graph 306, and/or generate an indication indicative of the second condition being met.

Graph 304 includes a representation of dQFRate_dt (e.g., the second derivative of the incremental capacity fade) over time. At point 314 (at around 5.4×10⁶ seconds), the second derivative of the change in the incremental battery capacity fade meets the second derivative threshold, e.g., that the second derivative of the incremental capacity fade is less than or less than or equal to the second derivative threshold. Processing circuitry 122 may determine that the first condition becomes true—that the second derivative of the plurality of incremental capacity fades meets the second derivative threshold. For example, the second derivative of the plurality of incremental capacity fades may meet the second derivative threshold when the second derivative of the plurality of incremental capacity fades is less than (or less than or equal to) the second derivative threshold. In the example of FIG. 3, the second derivative threshold may be −0.7, for example. Processing circuitry 122 may set a flag, e.g., EOS_Knee 326, from 0 to 1 as shown in graph 306, and/or generate an indication indicative of the first condition being met. For example, processing circuitry 122 may determine or detect a knee based on the second derivative of the plurality of incremental changes in the battery parameter meeting the second derivative threshold.

Graph 306 includes a representation of flags, EOS_dQFJump 316 and EOS_Knee 326. When processing circuitry 122 determines that the present change in the battery parameter is greater than (or greater than or equal to) the difference threshold (e.g., at the time 332 indicated by labeled point of graph 302), processing circuitry 122 may determine that a condition (e.g., the second condition) has been met. For example, processing circuitry 122 may assert a flag and/or generate an indication that is indicative of the condition being met. For example, EOS_dQFJump 316, which may be such a flag, moves from a value of 0 to a value of 1 when the condition is met.

When processing circuitry 122 determines that the second derivative of the change in the battery parameter over time is less than (or less than or equal to) a second derivative threshold (e.g., at the time indicated by point 314 of graph 304), processing circuitry 122 may determine that a condition (e.g., the first condition) has been met. For example, processing circuitry 122 may assert a flag and/or generate an indication that is indicative of the condition being met. For example, EOS_Knee 326, which may be such a flag, moves from a value of 0 to a value of 1 when the condition is met. Processing circuitry 122 may be configured to generate an indication for output and output such an indication based on either one of, or both of, the conditions of the example of FIG. 3 being met (e.g., EOS_dQFJump 316 and/or EOS-Knee 326 being equal to 1). For example, processing circuitry 122 may generate an indication upon a first (e.g., first in time) of the two conditions being met or may generate an indication only upon both of the conditions being met. In some examples, processing circuitry 122 may generate one indication upon the first in time of the two conditions being met and a second indication upon the second in time of the two conditions being met (at such time both conditions are met). Such indication(s) may include a warning or instruction to a user of a device powered by the battery to replace, or have replaced, the battery. In some examples, the indication may also include a predicted time-to-EOS.

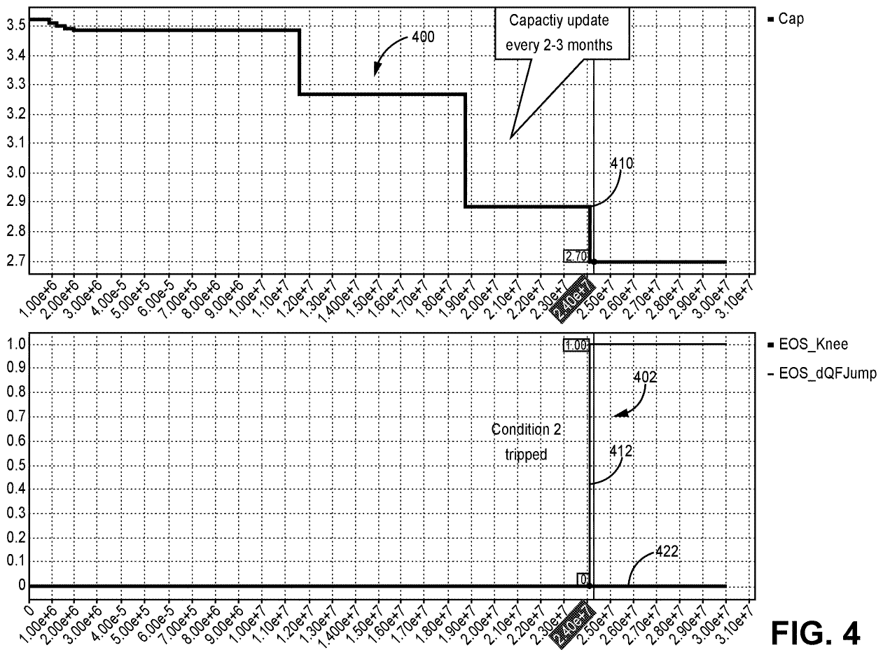

FIG. 4 is a graphical diagram illustrating example techniques for determining accelerating battery parameter changes over time with relatively infrequent battery parameter monitoring according to one or more aspects of this disclosure. While the example of FIG. 4 relates to fading battery capacity, the discussion may also be applicable to other changing battery parameters, such as battery impedance growth.

In the example of FIG. 4, processing circuitry 122 may determine the battery capacity on a relatively infrequent basis. For example, processing circuitry 122 may determine the battery capacity in the range of every 2-3 months, rather than every 100 hours, as in the example of FIG. 3. Determining the battery capacity on a less frequent basis may save some battery power, as processing circuitry 122 does not need to determine the battery capacity as often. However, this may lead to one or both of the aforementioned conditions not being detected prior to the battery reaching EOS.

Graph 400 depicts battery capacity as determined by processing circuitry 122 over time. At time 410, processing circuitry 122 may determine that the present change in the battery parameter is greater than (or greater than or equal to) the difference threshold. Thus, processing circuitry 122 may determine that a condition (e.g., the second condition) has been met.

Graph 402 depicts a representation of flags EOS_dQFJump 412 and EOS_Knee 422. As can be seen, at time 410 of Graph 400, processing circuitry 122 determines that the second condition is met and changes a value of flag (EOS-dQFJump 412) and/or generates an indication that is indicative of the condition being met. For example, EOS_dQFJump 412 moves from a value of 0 to a value of 1 when the condition is met. However, in this example, EOS_knee 422 does not move from the value of 0. For example, processing circuitry 122 may determine or detect a knee when the latest incremental capacity fade rate meets a difference threshold. The difference threshold may be an average of previous incremental changes in the parameter plus a percentage. This percentage may include a percentage of the average of the past incremental capacity fade rates, or a percentage of the latest incremental capacity fade rate, such as 20%, 40%, 60%, 80% or any other percentage value.

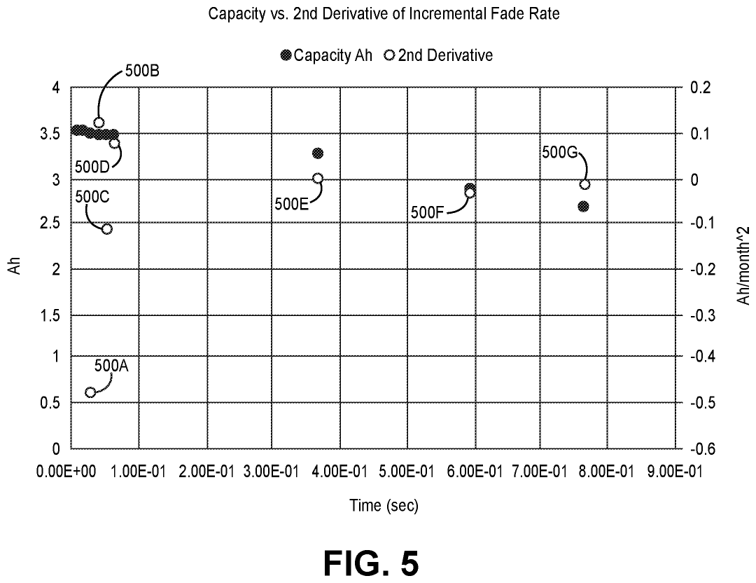

FIG. 5 is a conceptual diagram illustrating determined data points of battery parameter changes over time with relatively infrequent battery parameter monitoring according to one or more aspects of this disclosure. While the example of FIG. 5 relates to fading battery capacity, the discussion may also be applicable to other changing battery parameters, such as battery impedance growth.

In the example, of FIG. 5, only six data points for the second derivative of the change in capacity (data points 500A-500G) exist. The remaining data points shown are data points of the capacity of rechargeable battery 100. Processing circuitry 122 may be configured to not assert a condition (e.g., the first condition—the second derivative of the change in the battery capacity over time meeting a second derivative threshold) when there are not sufficient data points to provide a meaningful or accurate determination. As there are only 6 available data points for the second derivative of the change in capacity, processing circuitry 122 may not determine whether the second derivative of the change in the battery capacity meets the second derivative threshold. As such, processing circuitry 122 may not assert a flag, e.g., EOS_Knee 422 (FIG. 4), or generate an indication indicative of the second derivative of the change in battery over time meeting the second derivative threshold. Therefore, some implementors may desire to generate an indication based on a first of the conditions being met rather than both of the conditions being met.

FIG. 6 is a graphical diagram illustrating an example battery capacity fade curve over time. In the example of FIG. 6, battery capacity is shown on the y-axis and time is shown on the x-axis. Thus, battery capacity fade curve 600 depicts the battery capacity over time. The battery capacity fades over time as shown by battery capacity fade curve 600. As can be seen, there is a knee-like appearance (knee 602) to battery capacity fade curve 600 between time t2 and time t3.

Processing circuitry 122 may determine a capacity of battery 100 at times during the life of battery 100, for example, from time-to-time, periodically, or continuously. Processing circuitry 122 may also determine an incremental capacity fade rate of battery 100 based on determined capacities of battery 100. For example, at time t1, processing circuitry 122 may determine an incremental capacity fade rate based on the capacity values measured at t1 and t0. Processing circuitry 122 may similarly determine, at time t2, an incremental capacity fade rate based on the capacity values measured at t2 and t1, and may determine, at time t3, an incremental capacity fade rate based on the capacity values measured at t3 and t2.

Processing circuitry 122 may also determine a present capacity, and/or a predefined EOS capacity (CEOS). The predefined EOS capacity, CEOS, may be predefined and stored in memory 124 (e.g., in battery parameters 140 or thresholds 144). For example, at time t1, processing circuitry 122 may determine a present capacity based on the incremental capacity fade rate between times t1 and t0, as the present incremental capacity fade rate at time t1 may be the incremental capacity fade rate between the present time (t1) and a last or immediately previous determined capacity (t0).

For example, processing circuitry 122 may predict a time-to-EOS prediction based on the latest or most resent determined incremental capacity fade rate.

For example, processing circuitry 122 may determine the incremental capacity fade rate QF_{inc21} between t₂ and t₁ as

$${QF}_{inc \_ 2} = \frac{{C}_{2} - {C}_{1}}{{t}_{2} - {t}_{1}} = \frac{{C}_{0} * ( {QF}_{2} - {QF}_{1} )}{{t}_{2} - {t}_{1}}$$

where QF₁ and QF₂ are fade coefficients at t₁ and t₂, respectfully, normalized to C₀, C₀ is a capacity at time t0, C₁ is a capacity at time t₁, and C₂ is a capacity at time t₂. A QF may be a value between 0 and 1. For example, at t₁, if the capacity is 90% of the t₀ capacity (C₀), then QF₁ is 0.9. Processing circuitry may then determine whether either or both of the first condition or the second condition are met.

Processing circuitry 122 may determine, at time tᵢ, a time-to-EOS as

$${t}_{ti - EOS} = \frac{{C}_{i} - {C}_{EOS}}{{QF}_{inc \_ i}} = \frac{{C}_{0} * ( {QF}_{i} - {QF}_{EOS} )}{{QF}_{inc \_ i}}$$

where t_{ti-EOS} is the predicted time-to-EOS for the battery at a present time, C₀ is an original battery capacity, Cᵢ is the capacity at tᵢ, C_{EOS} is the capacity where EOS is defined, QFᵢ is the capacity at tᵢ as a ratio of to capacity C₀ (between 0 and 1), QF_{EOS} is a predefined EOS capacity ratio and Q_{fine_i} is the incremental capacity fade rate at tᵢ.

For example, the CEOs may be defined by a manufacturer of battery 100 (e.g., 80% of C₀) or may be definable by, for example, a purchaser of battery 100, a manufacturer of device 120, a purchaser of device 120, or the like. For example, if device 120 is a device that requires a relatively high current draw from battery 100 to power device 120, the C_{EOS} may be defined as a relatively higher value of the original capacity, such as 85% of C₀. In some examples, processing circuitry may employ the same algorithm or a similar algorithm to predict a time-to-EOS based on incremental impedance growth rate.

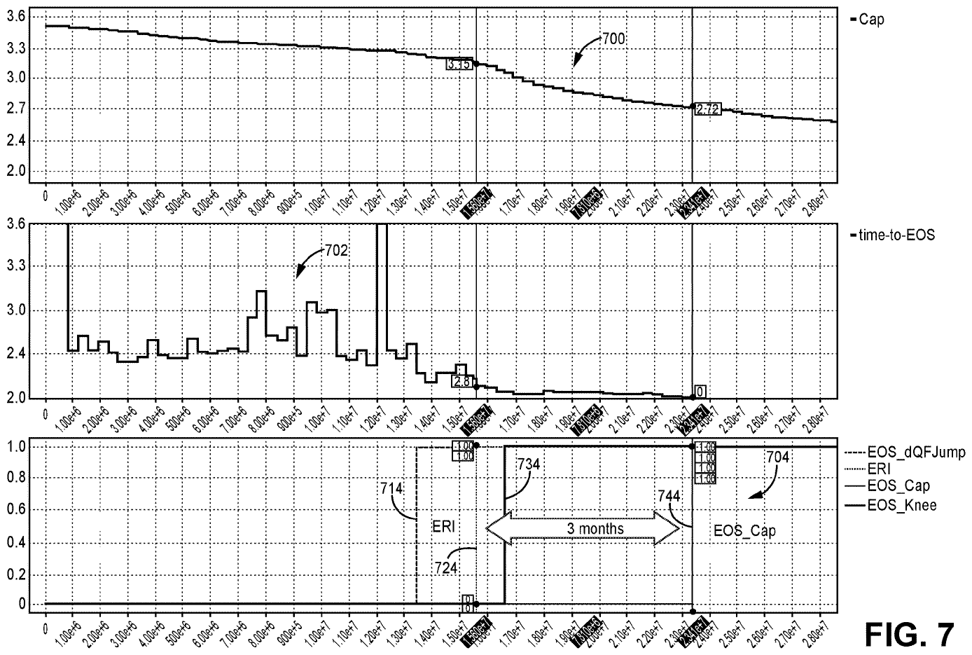

FIG. 7 is a graphical diagram illustrating example EOS prediction techniques according to one or more aspects of this disclosure. Graph 700 depicts a representation of battery capacity over time. Graph 702 depicts time-to-EOS determinations over time. For example, processing circuitry 122 may calculate or determine an estimate of time-to-EOS from time-to-time, periodically, or continuously. Graph 704 depicts representations of flags EOS_qDFJump 714, ERI 724, EOS_Knee 734, and EOS_Cap 744.

As in the example of FIG. 3, processing circuitry 122 may determine that a present change in the battery parameter meets a difference threshold and assert a flag or indication thereof (e.g., change a value of EOS_qDFJump 714 from 0 to 1). Processing circuitry 122 may also determine that a second derivative of the change in the battery parameter over time is less than a second derivative threshold and assert a flag or indication thereof (e.g., change a value of EOS_Knee 734 from 0 to 1). As discussed earlier herein, processing circuitry 122 may generate an indication and/or output an indication when either or both of these two conditions is met.

Additionally, or alternatively, processing circuitry 122 may determine an estimated time-to-EOS (e.g., an estimate that rechargeable battery 100 may reach EOS in X time) and compare the estimated time-to-EOS with a time-to-EOS threshold. In some examples, the time-to-EOS threshold may be a period of time such as 9 months, 6 months, 3 months, 2 months, 1 month, or some other period of time. Processing circuitry 122 may determine that the estimated time-to-EOS meets the time-to-EOS threshold (e.g., the estimated time-to EOS present time is less than (or equal to or less than) the time-to-EOS threshold). In such a case, when processing circuitry 122 determines that the estimated time-to-EOS meets the time-to-EOS threshold (e.g., is within 3 months of the EOS), processing circuitry 122 may assert a flag or indication, such as elective replacement indictor (ERI) 724 (e.g., change a value of ERI 724 from 0 to 1). In some examples, based on the estimated time-to-EOS meeting the time-to-EOS threshold, processing circuitry 122 may generate an indication and output the indication for a user of device 120. This indication may include an instruction or warning to replace, or have replaced, battery 100. In some examples, this indication may, additionally, or alternatively, include the estimated time-to-EOS, an estimated date of EOS, and/or some other indication of when battery 100 is expected to reach EOS.

Processing circuitry 122 may continue to determine an estimated time-to-EOS. If the user does not replace, or have replaced, battery 100, battery 100 may actually reach an EOS state. In such a case, processing circuitry 122 may determine that battery 100 has reached the EOS state, e.g., when the time-to-EOS is 0 or negative. Processing circuitry 122 may assert a flag or indication thereof (e.g., change a value of EOS_Cap 744 from 0 to 1). Processing circuitry 122 may generate an indication and output the indication, e.g., for viewing by a person, such as a user of device 120. In some examples, processing circuitry 122 may control UI 136 to output the indication to the person. In other examples, processing circuitry 122 may control communication circuitry 130 to transmit the indication to communication circuitry 158 and processing circuitry 152 may control UI 156 to output the indication to the person.

The example of FIG. 7 includes an example of processing circuitry 122 performing a continuous time-to-EOS calculation with the capacity fade curve which is the same as that of FIG. 6. Graph 702 depicts the time-to-EOS value as the capacity fades. In this example, the EOS capacity (CEOS) is 80% of beginning-of-life (BOL) capacity. When the time-to-EOS drops below 3 months (e.g., the time-to-EOS threshold), processing circuitry 122 may assert the ERI flag or indication by changing a value of the ERI flag from 0 to 1. Within three months of the ERI assertion, the time-to-EOS drop to zero (or negative) and processing circuitry 122 may assert a second indictor to alert the user of device 120 that EOS capacity has been reached.

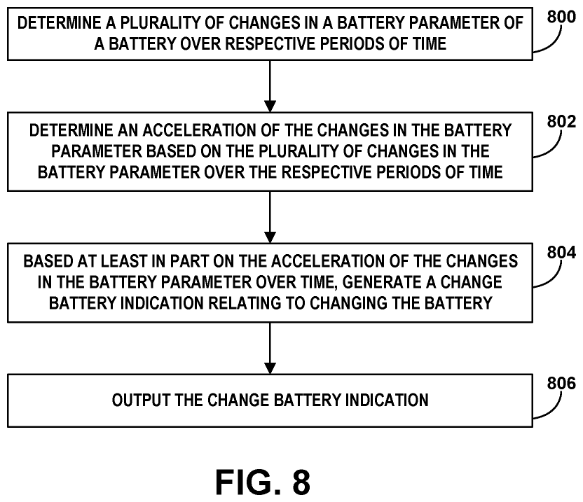

FIG. 8 is a flow diagram illustrating example state-of-health techniques according to one or more aspects of this disclosure. Processing circuitry 122 may determine a plurality of changes in a battery parameter of a battery over respective periods of time (800). For example, processing circuitry 122 may determine a battery parameter, such as battery capacity or battery impedance, of battery 100 at a plurality of different times. Processing circuitry 122 may determine changes or differences between the battery parameter between different times (e.g., between consecutive determinations of the battery parameter) to determine the plurality of changes in the battery parameter over the respective periods of time. These changes of battery parameters over time may represent, for example, incremental capacity fade rates or incremental impedance growth rates.

Processing circuitry 122 may determine an acceleration of the changes in the battery parameter based on the plurality of changes in the battery parameter over the respective periods of time (802). For example, processing circuitry 122 may determine that there is an acceleration in the changes in the battery parameter by either of, or both of, 1) a present change in the battery parameter meeting a difference threshold, or 2) a second derivative of the plurality of changes in the battery parameter over the respective periods of time meeting a second derivative threshold. For example, the difference threshold may be an average of a plurality of past changes in the battery parameter plus a predetermined percentage of a) the average of the plurality of past incremental changes in the battery parameter, or b) a latest incremental change in the battery parameter. For example, to meet the difference threshold, the present change in the battery parameter may be greater than, or equal to or greater than, the difference threshold. In some examples, the threshold distance may include a percentage of the average of the past incremental capacity fade rates, or a percentage of the latest incremental capacity fade rate, such as 20%, 40%, 60%, 80% or any other percentage value. For example, to meet the second derivative threshold, the second derivative of the plurality of changes in the battery parameter over the respective periods of time may be less than, or less than or equal to, the second derivative threshold. For example, the second derivative threshold may be a predetermined value, such as a value between 0 and −1. In some examples, the second derivative threshold may be −0.5, −0.6, −0.7, −0.8, or −0.9.

Processing circuitry 122 may, based at least in part on the acceleration of the changes in the battery parameter over time, generate a change battery indication relating to changing the battery (804). For example, if processing circuitry 122 determines that there is an acceleration of the changes in the battery parameter over time, processing circuitry 122 may generate a change battery indication. The change battery indication may inform a user of device 120 to change, or have changed, battery 100. In some examples, the change battery indication may include an indication of a predicted time-to-EOS of battery 100, so as to provide the user of device 120 with an estimate of when battery 100 may no longer be able to effectively power an intended use of device 120. For example, the indication of the predicted time-to-EOS may include a quantity of time until the predicted EOS (e.g., 2.5 months) and/or a date of the predicted EOS (e.g., Mar. 15, 2023).

Processing circuitry 122 may output the change battery indication (806). For example, processing circuitry 122 may control UI 136 to visually, audibly, tactilely or otherwise present the change battery indication to a user of device 120. Alternatively, or additionally, processing circuitry 122 may, for example, via communication circuitry 130, output the change battery indication to device 150 for presentation to the user of device 120. For example, the change battery indication may be presented to the user via a display, a speaker, a flashing light, a vibration of a device, or any combination thereof.

In some examples, the plurality of changes may be a plurality of incremental changes. In some examples, as part of determining the acceleration of the changes in the battery parameter, processing circuitry 122 may determine at least one of a) a present incremental change in the battery parameter meets a difference threshold, or b) a second derivative of a plurality of incremental changes in the battery parameter over the respective periods of time meets a second derivative threshold. For example, the difference threshold may include an average of a plurality of past incremental changes in the battery parameter plus a predetermined percentage of a) the average of the past incremental changes in the battery parameter, or b) a latest incremental change in the battery parameter.

In some examples, the change battery indication is a first change battery indication and processing circuitry 122 may generate the first change battery indication based on a first in time of a) the present change in the battery parameter meeting the difference threshold, or b) the second derivative of the plurality of changes in the battery parameter over the respective periods of time meeting the second derivative threshold. In some examples, processing circuitry 122 may determine a second in time of c) the present incremental change in the battery parameter meets a difference threshold, or d) the second derivative of the plurality of incremental changes in the battery parameter over the respective periods of time meets a second derivative threshold. Processing circuitry 122 may, based on a second in time of e) the present change in the battery parameter meeting the difference threshold, or f) the second derivative of the plurality of changes in the battery parameter over the respective periods of time meeting the second derivative threshold, output a second change battery indication. In some examples, the first change battery indication is the same as the second change battery indication, in which case the second change battery indication may already have been generated and, in some examples, stored in memory 124. In some examples, the second change battery indication is different than the first change battery indication and processing circuitry 122 is further configured to generate the second change battery indication.

In some examples, each of the plurality of changes in the battery parameter over the respective periods of time comprise an incremental capacity fade rate or an incremental impedance growth rate. In some examples, as part of determining the plurality of changes in the battery parameter over the respective periods of time, processing circuitry 122 may determine the incremental capacity fade rate, QF_{inc21}, between t₂ and t₁, as

$${QF}_{inc 21} = \frac{{C}_{2} - {C}_{1}}{{t}_{2} - {t}_{1}} = \frac{{C}_{0} * ( {QF}_{2} - {QF}_{1} )}{{t}_{2} - {t}_{1}}$$

where QF₁ and QF₂ are fade coefficients at t₁ and t₂, respectfully, normalized to C₀, C₀ is a capacity at time t₀, C₁ is a capacity at time t₁, and C₂ is a capacity at time t₂.

In some examples, processing circuitry 122 may determine a predicted time-to-EOS for the battery. In some examples, as part of determining the predicted time-to-EOS for the battery, processing circuitry 122 may determine

$${t}_{ti - EOS} = \frac{{C}_{i} - {C}_{EOS}}{{QF}_{inc \_ i}} = \frac{{C}_{0} * ( {QF}_{i} - {QF}_{EOS} )}{{QF}_{inc \_ i}}$$

where t_{ti-EOS} is the predicted time to end of service for the battery at a present time, C₀ is an original battery capacity, Cᵢ is a battery capacity at a present time, C_{EOS} is a battery capacity at EOS, and Q_{fine_i} is the incremental capacity fade rate at the present time.

In some examples, the change battery indication comprises a representation of a predicted time-to-EOS. In some examples, processing circuitry 122 may determine that the predicted time-to-EOS meets a time-to-EOS threshold. Processing circuitry 122 may, based on the predicted time-to-EOS meeting the time-to-EOS threshold, generate an end of service warning, the end of service warning comprising at least one of an indication that the battery is within a predetermined time of the predicted time-to-EOS or an indication of the predicted time-to-EOS. Processing circuitry 122 may output the end of service warning.

In some examples, processing circuitry 122 may determine that the predicted time-to-EOS has reached zero. Processing circuitry 122 may, based on the predicted time-to-EOS reaching zero, generate an EOS notification, the EOS notification being indicative that the battery has reached the EOS capacity. Processing circuitry 122 may output the EOS notification.

Device 120 may include electronics and other internal components necessary or desirable for executing the functions associated with the device. Device 120 may include or may be one or more processors or processing circuitry, such as one or more digital signal processors (DSPs), general purpose microprocessors, application specific integrated circuits (ASICs), field programmable logic arrays (FPGAs), or other equivalent integrated or discrete logic circuitry. Accordingly, the term “processor” and “processing circuitry” as used herein may refer to any of the foregoing structure or any other structure suitable for implementation of the techniques described herein.

Memory 124 may include any volatile or non-volatile media, such as a random-access memory (RAM), read only memory (ROM), non-volatile RAM (NVRAM), electrically erasable programmable ROM (EEPROM), flash memory, and the like. Memory 124 may be a storage device or other non-transitory medium.

This disclosure includes the following non-limiting examples.
Example 1. A device comprising: a memory; a battery; processing circuitry coupled to the memory, the processing circuitry being configured to: determine a plurality of changes in a battery parameter of a battery over respective periods of time; determine an acceleration of the changes in the battery parameter based on the plurality of changes in the battery parameter over the respective periods of time; based at least in part on the acceleration of the changes in the battery parameter over time, generate a change battery indication relating to changing the battery; and output the change battery indication.
Example 2. The device of example 1, wherein as part of determining the acceleration of the changes in the battery parameter, the processing circuitry is configured to determine at least one of a) a present incremental change in the battery parameter meets a difference threshold, or b) a second derivative of a plurality of incremental changes in the battery parameter over the respective periods of time meets a second derivative threshold.
Example 3. The device of example 2, wherein the difference threshold comprises an average of a plurality of past incremental changes in the battery parameter plus a predetermined percentage of a) the average of the past incremental changes in the battery parameter, or b) a latest incremental change in the battery parameter.
Example 4. The device of any of examples 1-3, wherein the change battery indication is a first change battery indication and wherein the processing circuitry is configured to generate the first change battery indication based on a first in time of a) the present change in the battery parameter meeting the difference threshold, or b) the second derivative of the plurality of changes in the battery parameter over the respective periods of time meeting the second derivative threshold, and wherein the processing circuitry is further configured to: determine a second in time of c) the present incremental change in the battery parameter meets a difference threshold, or d) the second derivative of the plurality of incremental changes in the battery parameter over the respective periods of time meets a second derivative threshold; and based on a second in time of e) the present change in the battery parameter meeting the difference threshold, or f) the second derivative of the plurality of changes in the battery parameter over the respective periods of time meeting the second derivative threshold, output a second change battery indication.
Example 5. The device of example 4, wherein the second change battery indication is different than the first change battery indication and the processing circuitry is further configured to generate the second change battery indication.
Example 6. The device of any of examples 1-5, wherein each of the plurality of changes in the battery parameter over the respective periods of time comprise an incremental capacity fade rate or an incremental impedance growth rate.
Example 7. The device of example 6, wherein as part of determining the plurality of changes in the battery parameter over the respective periods of time, the processing circuitry is configured to determine the incremental capacity fade rate, QF_{inc21}, between t₂ and t₁, as

$${QF}_{inc 21} = \frac{{C}_{2} - {C}_{1}}{{t}_{2} - {t}_{1}} = \frac{{C}_{0} * ( {QF}_{2} - {QF}_{1} )}{{t}_{2} - {t}_{1}}$$

where QF₁ and QF₂ are fade coefficients at t₁ and t₂, respectfully, normalized to C₀, C₀ is a capacity at time t0, C₁ is a capacity at time t1, and C₂ is a capacity at time t2.
Example 8. The device of any of examples 1-7, wherein the processing circuitry is further configured to determine a predicted time-to-end of service (EOS) for the battery.
Example 9. The device of example 8, wherein as part of determining the predicted time-to-EOS for the battery, the processing circuitry is configured to determine

$${t}_{ti - EOS} = \frac{{C}_{i} - {C}_{EOS}}{{QF}_{inc \_ i}} = \frac{{C}_{0} * ( {QF}_{i} - {QF}_{EOS} )}{{QF}_{inc \_ i}}$$

where t_{ti-EOS} is the predicted time-to-EOS for the battery at a present time, C₀ is an original battery capacity, Cᵢ is a battery capacity at time tᵢ, C_{EOS} is a battery capacity at EOS, QFᵢ is the capacity at time tᵢ as a ratio of to capacity C₀, QF_{EOS} is a predefined EOS capacity ratio, and Q_{finc_i} is the incremental capacity fade rate at the present time.
Example 10. The device of example 8 or example 9, wherein the change battery indication comprises a representation of the predicted time-to-EOS.
Example 11. The device of any of examples 8-10, wherein the processing circuitry is further configured to: determine that the predicted time-to-EOS meets a time-to-EOS threshold; based on the predicted time-to-EOS meeting the time-to-EOS threshold, generate an EOS warning, the EOS warning comprising at least one of an indication that the battery is within a predetermined time of the predicted time-to-EOS or an indication of the predicted time-to-EOS; and output the EOS warning.
Example 12. The device of any of examples 1-11, wherein the processing circuitry is further configured to: determine that a predicted time-to-end of service (EOS) has reached zero; based on the predicted time-to-EOS reaching zero, generate an EOS notification, the EOS notification being indicative that the battery has reached EOS capacity; and output the EOS notification.
Example 13. A method comprising: determining a plurality of changes in a battery parameter of a battery over respective periods of time; determining an acceleration of the changes in the battery parameter based on the plurality of changes in the battery parameter over the respective periods of time; based at least in part on the acceleration of the changes in the battery parameter over time, generating a change battery indication relating to changing the battery; and outputting the change battery indication.
Example 14. The method of example 13, wherein determining the acceleration of the changes in the battery parameter comprises determining at least one of: a) a present incremental change in the battery parameter meets a difference threshold, or b) a second derivative of a plurality of incremental changes in the battery parameter over the respective periods of time meets a second derivative threshold.
Example 15. The method of example 14, wherein the difference threshold comprises an average of a plurality of past incremental changes in the battery parameter plus a predetermined percentage of a) the average of the past incremental changes in the battery parameter, or b) a latest incremental change in the battery parameter.
Example 16. The method of any of examples 13-15, wherein the change battery indication is a first change battery indication and wherein generating the first change battery indication is based on a first in time of a) the present change in the battery parameter meeting the difference threshold, or b) the second derivative of the plurality of changes in the battery parameter over the respective periods of time meeting the second derivative threshold, and wherein method further comprises: determining a second in time of c) the present incremental change in the battery parameter meets a difference threshold, or d) the second derivative of the plurality of incremental changes in the battery parameter over the respective periods of time meets a second derivative threshold; and based on a second in time of e) the present change in the battery parameter meeting the difference threshold, or f) the second derivative of the plurality of changes in the battery parameter over the respective periods of time meeting the second derivative threshold, outputting a second change battery indication.
Example 17. The method of example 16, wherein the second change battery indication is different than the first change battery indication and wherein the method further comprises generating the second change battery indication.
Example 18. The method of any of examples 13-17, wherein the plurality of changes in the battery parameter over the respective periods of time comprise an incremental capacity fade rate or an incremental impedance growth rate.
Example 19. The method of example 18, wherein determining the plurality of changes in the battery parameter over the respective periods of time comprises determining the incremental capacity fade rate, QF_{inc21}, between t₂ and t₁, as

$${QF}_{inc 21} = \frac{{C}_{2} - {C}_{1}}{{t}_{2} - {t}_{1}} = \frac{{C}_{0} * ( {QF}_{2} - {QF}_{1} )}{{t}_{2} - {t}_{1}}$$

where QF₁ and QF₂ are fade coefficients at t₁ and t₂, respectfully, normalized to C₀, C₀ is a capacity at time t0, C₁ is a capacity at time t1, and C₂ is a capacity at time t2.
Example 20. The method of any of examples 13-19, further comprising determining a predicted time-to-end of service (EOS) for the battery.
Example 21. The method of example 20, wherein determining the predicted time-to-EOS for the battery comprises determining

$${t}_{ti - EOS} = \frac{{C}_{i} - {C}_{EOS}}{{QF}_{inc \_ i}} = \frac{{C}_{0} * ( {QF}_{i} - {QF}_{EOS} )}{{QF}_{inc \_ i}}$$

where t_{ti-EOS} is the predicted time-to-EOS for the battery at a present time, C₀ is an original battery capacity, Cᵢ is a battery capacity at time tᵢ, C_{EOS} is a battery capacity at EOS, QFᵢ is the capacity at time tᵢ as a ratio of to capacity C₀, QF_{EOS} is a predefined EOS capacity ratio, and Q_{fine_i} is the incremental capacity fade rate at the present time.
Example 22. The method of example 20 or example 21, wherein the change battery indication comprises a representation of a predicted time-to-EOS.
Example 23. The method of any of examples 20-22, further comprising: determining that the predicted time to the end of service meets a time-to-EOS threshold; based on the predicted time-to-EOS meeting the time-to-EOS threshold, generating an EOS warning, the EOS warning comprising at least one of an indication that the battery is within a predetermined time of the predicted time-to-EOS or an indication of the predicted time-to-EOS; and outputting the EOS warning.
Example 24. The method of any of examples 13-23, further comprising: determining that a predicted time-to-end of service (EOS) has reached zero; based on the predicted time-to-EOS reaching zero, generating an EOS notification, the EOS notification being indicative that the battery has reached EOS capacity; and outputting the EOS notification.
Example 25. A non-transitory storage medium comprising instructions that when executed by one or more processors cause the one or more processors to: determine a plurality of changes in a battery parameter of a battery over respective periods of time; determine an acceleration of the changes in the battery parameter based on the plurality of changes in the battery parameter over the respective periods of time; based at least in part on the acceleration of the changes in the battery parameter over time, generate a change battery indication relating to changing the battery; and output the change battery indication.

Various examples have been described in the disclosure. These and other examples are within the scope of the following claims.

1. A device comprising:
a memory;
a battery; and
processing circuitry coupled to the memory, the processing circuitry being configured to:
determine a plurality of changes in a battery parameter of the battery over respective periods of time;
determine an acceleration of the changes in the battery parameter based on the plurality of changes in the battery parameter over the respective periods of time;
based at least in part on the acceleration of the changes in the battery parameter over time, generate a change battery indication relating to changing the battery; and
output the change battery indication.

2. The device of claim 1, wherein as part of determining the acceleration of the changes in the battery parameter, the processing circuitry is configured to determine at least one of a) a present incremental change in the battery parameter meets a difference threshold, or b) a second derivative of a plurality of incremental changes in the battery parameter over the respective periods of time meets a second derivative threshold.

3. The device of claim 2, wherein the difference threshold comprises an average of a plurality of past incremental changes in the battery parameter plus a predetermined percentage of a) the average of the plurality of past incremental changes in the battery parameter, or b) a latest incremental change in the battery parameter.

4. The device of claim 1, wherein the change battery indication is a first change battery indication and wherein the processing circuitry is configured to generate the first change battery indication based on a first in time of a) a present incremental change in the battery parameter meeting a difference threshold, or b) a second derivative of a plurality of incremental changes in the battery parameter over the respective periods of time meeting a second derivative threshold, and wherein the processing circuitry is further configured to:
determine a second in time of c) the present incremental change in the battery parameter meeting the difference threshold, or d) the second derivative of the plurality of incremental changes in the battery parameter over the respective periods of time meeting the second derivative threshold; and
based on the second in time of e) the present incremental change in the battery parameter meeting the difference threshold, or f) the second derivative of the plurality of incremental changes in the battery parameter over the respective periods of time meeting the second derivative threshold, output a second change battery indication.

5. The device of claim 4, wherein the second change battery indication is different than the first change battery indication and the processing circuitry is further configured to generate the second change battery indication.

6. The device of claim 1, wherein each of the plurality of changes in the battery parameter over the respective periods of time comprise an incremental capacity fade rate or an incremental impedance growth rate.

7. The device of claim 6, wherein as part of determining the plurality of changes in the battery parameter over the respective periods of time, the processing circuitry is configured to determine the incremental capacity fade rate, QF_{inc21}, between t₂ and t₁, as
$${QF}_{inc 21} = \frac{{C}_{2} - {C}_{1}}{{t}_{2} - {t}_{1}} = \frac{{C}_{0} * ( {QF}_{2} - {QF}_{1} )}{{t}_{2} - {t}_{1}}$$
where QF₁ and QF₂ are fade coefficients at t₁ and t₂, respectfully, normalized to C₀, C₀ is a capacity at time t0, C₁ is a capacity at time t1, and C₂ is a capacity at time t2.

8. The device of claim 1, wherein the processing circuitry is further configured to determine a predicted time-to-end of service (EOS) for the battery.

9. The device of claim 8, wherein as part of determining the predicted time-to-EOS for the battery, the processing circuitry is configured to determine
$${t}_{ti - EOS} = \frac{{C}_{i} - {C}_{EOS}}{{QF}_{inc \_ i}} = \frac{{C}_{0} * ( {QF}_{i} - {QF}_{EOS} )}{{QF}_{inc \_ i}}$$
where t_{ti-EOS} is the predicted time-to-EOS for the battery at a present time, C₀ is an original battery capacity, Cᵢ is a battery capacity at time tᵢ, C_{EOS} is a battery capacity at EOS, QFᵢ is a capacity at time tᵢ as a ratio of to capacity C₀, QF_{EOS} is a predefined EOS capacity ratio, and Q_{finc_i} is an incremental capacity fade rate at the present time.

10. The device of claim 8, wherein the change battery indication comprises a representation of the predicted time-to-EOS.

11. The device of claim 8, wherein the processing circuitry is further configured to:
determine that the predicted time-to-EOS meets a time-to-EOS threshold;
based on the predicted time-to-EOS meeting the time-to-EOS threshold, generate an EOS warning, the EOS warning comprising at least one of an indication that the battery is within a predetermined time of the predicted time-to-EOS or an indication of the predicted time-to-EOS; and
output the EOS warning.

12. The device of claim 1, wherein the processing circuitry is further configured to:
determine that a predicted time-to-end of service (EOS) has reached zero;
based on the predicted time-to-EOS reaching zero, generate an EOS notification, the EOS notification being indicative that the battery has reached EOS capacity; and
output the EOS notification.

13. A non-transitory storage medium comprising instructions that when executed by one or more processors cause the one or more processors to:
determine a plurality of changes in a battery parameter of a battery over respective periods of time;
determine an acceleration of the changes in the battery parameter based on the plurality of changes in the battery parameter over the respective periods of time;
based at least in part on the acceleration of the changes in the battery parameter over time, generate a change battery indication relating to changing the battery; and
output the change battery indication.

14. A method comprising:
determining a plurality of changes in a battery parameter of a battery over respective periods of time;
determining an acceleration of the changes in the battery parameter based on the plurality of changes in the battery parameter over the respective periods of time;
based at least in part on the acceleration of the changes in the battery parameter over time, generating a change battery indication relating to changing the battery; and
outputting the change battery indication.

15. The method of claim 14, wherein determining the acceleration of the changes in the battery parameter comprises determining at least one of: a) a present incremental change in the battery parameter meets a difference threshold, or b) a second derivative of a plurality of incremental changes in the battery parameter over the respective periods of time meets a second derivative threshold.

16. The method of claim 15, wherein the difference threshold comprises an average of a plurality of past incremental changes in the battery parameter plus a predetermined percentage of a) the average of the plurality of past incremental changes in the battery parameter, or b) a latest incremental change in the battery parameter.

17. The method of claim 14, wherein the change battery indication is a first change battery indication and wherein generating the first change battery indication is based on a first in time of a) a present incremental change in the battery parameter meeting a difference threshold, or b) a second derivative of a plurality of incremental changes in the battery parameter over the respective periods of time meeting a second derivative threshold, and wherein method further comprises:
determining a second in time of c) the present incremental change in the battery parameter meeting the difference threshold, or d) the second derivative of the plurality of incremental changes in the battery parameter over the respective periods of time meeting the second derivative threshold; and
based on the second in time of e) the present incremental change in the battery parameter meeting the difference threshold, or f) the second derivative of the plurality of incremental changes in the battery parameter over the respective periods of time meeting the second derivative threshold, outputting a second change battery indication.

18. The method of claim 17, wherein the second change battery indication is different than the first change battery indication and wherein the method further comprises generating the second change battery indication.

19. The method of claim 14, wherein the plurality of changes in the battery parameter over the respective periods of time comprise an incremental capacity fade rate or an incremental impedance growth rate.

20. The method of claim 19, wherein determining the plurality of changes in the battery parameter over the respective periods of time comprises determining the incremental capacity fade rate, QF_{inc21}, between t₂ and t₁, as
$${QF}_{inc 21} = \frac{{C}_{2} - {C}_{1}}{{t}_{2} - {t}_{1}} = \frac{{C}_{0} * ( {QF}_{2} - {QF}_{1} )}{{t}_{2} - {t}_{1}}$$
where QF₁ and QF₂ are fade coefficients at t₁ and t₂, respectfully, normalized to C₀, C₀ is a capacity at time t0, C₁ is a capacity at time t1, and C₂ is a capacity at time t2.
